(19) United States
(12) Patent Application Publication
(10) Pub. No.: US 2025/0180653 A1
(43) Pub. Date: Jun. 5, 2025

(54) NONLINEARITY CHARACTERIZATION AND COMPENSATION FOR BATTERY DYNAMIC POWER PREDICTION

(71) Applicant: Cirrus Logic International Semiconductor Ltd., Edinburgh (GB)

(72) Inventors: Narayan KOVVALI, Tempe, AZ (US); Ying LI, Chandler, AZ (US); Seth SUPPAPPOLA, Tempe, AZ (US)

(73) Assignee: Cirrus Logic International Semiconductor Ltd., Edinburgh (GB)

(21) Appl. No.: 18/966,325

(22) Filed: Dec. 3, 2024

Related U.S. Application Data
(60) Provisional application No. 63/606,179, filed on Dec. 5, 2023.

(51) Int. Cl. G01R 31/367; G01R 31/374; G01R 31/3842; G01R 31/389

(52) U.S. Cl. CPC G01R 31/367; G01R 31/374; G01R 31/3842; G01R 31/389

(57) ABSTRACT

A method for battery power management based on battery nonlinearity characterization and compensation using a nonlinear resistor-capacitor (RC) equivalent circuit model (ECM) may include: measuring a current, a terminal voltage, and a temperature of a battery; implementing the nonlinear RC ECM comprising fixed, logarithmically spaced time constants and current dependent resistances and capacitances; constraining resistances of the nonlinear RC ECM to be nonnegative and performing a nonlinearity characterization procedure using the nonlinear RC ECM configured to characterize variations of a battery impedance with current amplitudes over a range of frequencies and create ECM parameter variations with current amplitudes by fitting impedance variations by nonlinear RC ECMs; performing online estimation of the nonlinear RC ECM using a battery current and a terminal voltage of the battery over time; and modifying the online estimated nonlinear RC ECM using ECM parameter variations to compensate for nonlinearity of the battery.

### RELATED APPLICATIONS

The present application claims priority to U.S. Provisional Patent Application Ser. No. 63/606,179, filed of Dec. 5, 2023, which is incorporated by reference herein in its entirety.

The present application is also related to U.S. patent application Ser. No. 18/608,617, filed Mar. 18, 2024, U.S. Provisional Patent Application 63/605,003, filed Dec. 1, 2023, U.S. patent application Ser. No. 18/628,374, filed Apr. 4, 2024, U.S. Provisional Patent Application Ser. No. 63/605,031, filed Dec. 1, 2023, U.S. patent application Ser. No. 18/828,879, filed Sep. 9, 2024, and U.S. Provisional Patent Application Ser. No. 63/606,389, filed Dec. 5, 2023, all of which are incorporated by reference herein in their entireties.

### FIELD OF DISCLOSURE

The present disclosure relates in general to battery modeling and management, including without limitation characterizing and compensating for nonlinearity of a battery and for performing dynamic power prediction for the battery.

### BACKGROUND

Lithium-ion batteries have become ubiquitous in the past few decades and are widely used in many applications, such as consumer electronic devices and electric vehicles. There is a limited amount of energy and power in a battery that is safely usable without risk of damage to the battery, and the accurate dynamic prediction of the available power is needed for many of these applications. For example, accurate dynamic power prediction of the battery in a smartphone may reduce the need for processor throttling, speaker volume limiting, screen brightness reduction, and adjustment of other power intensive operations. Preventing unnecessary power throttling may improve the overall user experience of a smartphone.

For real-time battery management applications, a battery's voltage response for an applied load current is typically described using an equivalent circuit model (ECM). An example is the well-known resistor-capacitor (RC) ECM. ECMs are much simpler and more efficient to implement compared to physics-based models (PBMs). An ECM may be estimated online using the measured load current and terminal voltage of the battery during normal operation, and then used for predicting the available power.

However, a battery's response is nonlinear, i.e., its impedance may vary significantly with load current amplitude, especially at low temperatures. In the Doyle-Fuller-Newman (DFN) pseudo-two-dimensional (P2D) and single-particle PBMs of a battery, the nonlinear charge transfer process at the surface of a particle in the electrode is represented by the Butler-Volmer (BV) relationship:

$${i}_{f} = {i}_{0} [ exp ( \frac{( 1 - α ) F}{R T} η ) - exp ( - \frac{α F}{R T} η ) ] ,$$

where q denotes the overpotential and i_{f} represents the faradaic current, i₀ represents the exchange current, a is the charge transfer coefficient, R is the gas constant, T is temperature, and F is the Faraday constant. The model describes a charge transfer resistance r_{CT}:

$${r}_{CT} ( {i}_{f} ) = \frac{η}{{i}_{f}} ,$$

that is dependent on the faradaic current i_{f}. In particular, the charger-transfer resistance decreases as the current amplitude increases (for both charge and discharge). Battery nonlinearity has been shown experimentally as well, including research in which the current dependent direct-current (DC) resistance was calculated using discharge current pulses.

Unfortunately, the typical dynamic load of a smartphone may not contain sustained high currents (for example, the average discharge current of a smartphone battery during audio streaming may only be about 0.8 A), and due to the nonlinearity, the low current amplitude (large charge transfer resistance) ECM estimated online may be different from the high current amplitude (small charge transfer resistance) ECM needed for power limit prediction.

Accounting for battery nonlinearity is critical for accurate power prediction because using a model estimated from low current amplitude for power prediction at a high current amplitude may lead to a possibly significant under-prediction of the available power, which may result in unnecessary device power throttling.

Several works have investigated battery ECMs that include nonlinearity models. These nonlinear ECMs include a linear model portion (i.e., a current independent model portion) and a nonlinear model portion (i.e., current dependent model portion). For example, in one approach, a fractional-order ECM was defined with a BV relation based current dependent charge transfer resistance, and the model parameters were estimated offline using electrochemical impedance spectroscopy (EIS) measurements with DC currents superimposed to define the amplitude set point. In another approach, a discretized transmission line ECM was developed with BV relation based current dependent resistors. In other approaches, RC and physics-based fractional-order ECMs were defined with a current dependent charge transfer resistance based on the BV relation, and the model parameters were estimated offline using EIS. In yet another approach, an RC ECM with a current dependent resistance and BV relation and piecewise polynomial models of the nonlinearity were used for state-of-power estimation. In another approach, a simple single RC element ECM with a logarithmic-type model of the current dependent polarization resistance was used for power prediction. The polarization resistance was estimated using pulse currents of various amplitudes. In another approach, a lumped-parameter PBM is developed in which the current dependent charge transfer resistance is modeled by the BV relation, and the nonlinear resistance is estimated offline using very short duration current pulses.

The use of the BV or other analytical models of charge transfer nonlinearity simplifies implementation in these methods, but because the actual cell-scale nonlinearity may not follow the analytical single-particle BV curve exactly due to variations in particle stoichiometry, Faradaic flux, etc., the nonlinearity may not be characterized with sufficient fidelity. Relying on offline characterization alone may also be problematic, because the impedance changes as the battery ages and may show significant variability between batteries depending on the usage history.

### SUMMARY

In accordance with the teachings of the present disclosure, certain disadvantages and problems associated with battery modeling and management have been reduced or eliminated.

In accordance with embodiments of the present disclosure, a method for battery power management based on battery nonlinearity characterization and compensation using a physics-based nonlinear fractional-order equivalent circuit model (ECM) may include measuring a battery current, a battery terminal voltage, and a battery temperature. The method may also include implementing the physics-based nonlinear fractional-order ECM comprising a linear model portion that represents current independent physics and a nonlinear model portion that represents current dependent physics, wherein the current independent physics and the current dependent physics are separately maintained. The method may additionally include performing a nonlinearity characterization procedure using the physics-based nonlinear fractional-order ECM configured to characterize variations of a battery impedance of a battery with current amplitudes over a range of frequencies and create ECM parameter variations with current amplitudes by fitting impedance variations by nonlinear fractional-order ECMs. The method may further include performing an online estimation of a fractional-order ECM using a battery load current and a battery terminal voltage of the battery over time to generate an online estimated fractional-order ECM and modifying the online estimated fractional-order ECM using ECM parameter variations to compensate for nonlinearity of the battery.

In accordance with embodiments of the present disclosure, a method for battery power management based on battery nonlinearity characterization and compensation using a nonlinear resistor-capacitor (RC) equivalent circuit model (ECM) may include measuring a battery current, a battery terminal voltage, and a battery temperature of a battery. The method may also include implementing the nonlinear RC ECM comprising fixed, logarithmically spaced time constants and current dependent resistances and capacitances and constraining resistances of the nonlinear RC ECM to be nonnegative. The method may additionally include performing a nonlinearity characterization procedure using the nonlinear RC ECM configured to characterize variations of a battery impedance with current amplitudes over a range of frequencies and create ECM parameter variations with current amplitudes by fitting impedance variations by nonlinear RC ECMs. The method may further include performing online estimation of the nonlinear RC ECM using a battery current and a terminal voltage of the battery over time to generate an online estimated nonlinear RC ECM and modifying the online estimated nonlinear RC ECM using ECM parameter variations to compensate for nonlinearity of the battery.

Technical advantages of the present disclosure may be readily apparent to one having ordinary skill in the art from the figures, description and claims included herein. The objects and advantages of the embodiments will be realized and achieved at least by the elements, features, and combinations particularly pointed out in the claims.

It is to be understood that both the foregoing general description and the following detailed description are explanatory examples and are not restrictive of the claims set forth in this disclosure.

### BRIEF DESCRIPTION OF THE DRAWINGS

A more complete understanding of the example, present embodiments and certain advantages thereof may be acquired by referring to the following description taken in conjunction with the accompanying drawings, in which like reference numbers indicate like features, and wherein:

FIG. 1 illustrates a block diagram of an example battery dynamic power prediction system with a nonlinear ECM and offline and online nonlinearity characterization along with online ECM estimation and nonlinearity compensation, in accordance with embodiments of the present disclosure;

FIG. 2 illustrates an example nonlinear RC ECM with an open-circuit voltage (OCV), a current independent series resistance, and current dependent RC resistances and capacitances, in accordance with embodiments of the present disclosure;

FIG. 3A illustrates an example physics-based nonlinear fractional-order ECM with an OCV, current independent series resistance, solid-electrolyte interface (SEI) and diffusion ZARC elements, and a current dependent charge transfer ZARC element, in accordance with embodiments of the present disclosure;

FIG. 3B illustrates an example physics-based nonlinear fractional-order ECM with an OCV, current independent series resistance, SEI and diffusion ZARC elements, and two current dependent charge transfer ZARC elements, in accordance with embodiments of the present disclosure;

FIG. 3C illustrates an example physics-based nonlinear fractional-order ECM with an OCV, current independent series resistance and SEI ZARC element, and current dependent charge transfer and diffusion ZARC elements, in accordance with embodiments of the present disclosure;

FIGS. 4A, 4B, and 4C illustrate block diagrams of example architectures that may be used for RC ECM fitting in the offline and online nonlinearity characterization and online RC ECM estimation, respectively, in accordance with embodiments of the present disclosure;

FIG. 5A illustrates a plot of the impedance variation with current amplitude in a new lithium-ion battery at a state-of-charge (SOC) equal to 20% and temperature equal to 25° C., in accordance with embodiments of the present disclosure;

FIG. 5B illustrates a plot of the physics-based nonlinear fractional-order ECM current dependent charge transfer resistance of a new lithium-ion battery at a SOC equal to 20% and temperature equal to 25° C., in accordance with embodiments of the present disclosure;

FIG. 5C illustrates a surface plot of the RC ECM current dependent RC resistances as a function of time constant and current amplitude for a new lithium-ion battery at a SOC equal to 20% and temperature equal to 25° C., in accordance with embodiments of the present disclosure;

FIGS. 6A and 6B illustrate block diagrams of example architectures that may be used for the physics-based fractional-order ECM fitting in the offline and online nonlinearity characterization and online physics-based fractional-order ECM estimation, in accordance with embodiments of the present disclosure; and

FIG. 7 illustrates a block diagram of an example architecture that may be used for nonparametric impedance estimation, in accordance with embodiments of the present disclosure.

### DETAILED DESCRIPTION

Embodiments of the present disclosure may provide a battery dynamic power prediction method that utilizes a nonlinear ECM and offline and online nonlinearity characterization along with online ECM estimation and nonlinearity compensation.

Two different nonlinear ECMs may be considered. The first is a nonlinear RC ECM with fixed, logarithmically spaced RC time constants and adjustable nonnegative resistances. The second is a physics-based nonlinear fractional-order ECM comprised of current dependent ZARC elements.

Offline and online application of broadband pulse load currents may be used to characterize the variation of the battery impedance with current amplitude for various SOCs, temperatures, and ages. The current dependent battery impedance may be modeled and estimated over a range of frequencies parametrically by fitting a nonlinear ECM using least-squares optimization, and a lookup table of ECM parameter variations for various operating set points may be created and maintained. The lookup table may allow for a faithful representation of the measured battery nonlinearity without constraining it to any specific analytical model. The creation and maintenance of a lookup table may also be crucial for eliminating the need for frequent online augmentation of high-current pulses.

The measured battery dynamic load current and terminal voltage during normal operation may be used to estimate an ECM online. The RC ECM with fixed, logarithmically spaced RC time constants and nonnegative resistances may be estimated efficiently via projected gradient descent optimization. For efficient online estimation of the fractional-order ECM, either parametric or nonparametric impedance estimation may be used, followed by nonlinear least-squares optimization in frequency domain. The parametric RC ECM impedance estimate may exhibit good convergence and tracking capability for impedance variations due to changes in current amplitude, SOC, or temperature. Nonparametric impedance estimation may trade off some convergence speed at low frequencies for improvement in computational efficiency.

Online nonlinearity compensation may be performed by modifying the online estimated ECM parameters during power prediction to account for the battery nonlinearity. Specifically, the power limits may be predicted using the online estimated ECM with lookup table-based modifications to the ECM parameters to compensate for the impedance change due to the difference between the estimation current amplitude and prediction current amplitude.

While the present disclosure focuses mainly on the problem of battery power limit prediction, the systems and methods disclosed herein may be broadly applicable to other battery power management tasks that involve high current amplitudes and where nonlinearity needs to be accounted for, for example, in fast charging.

Described below are the nonlinear ECMs and the nonlinearity characterization approaches, efficient algorithms for estimating the ECMs, and the proposed nonlinearity compensation methodology, in accordance with embodiments of the present disclosure.

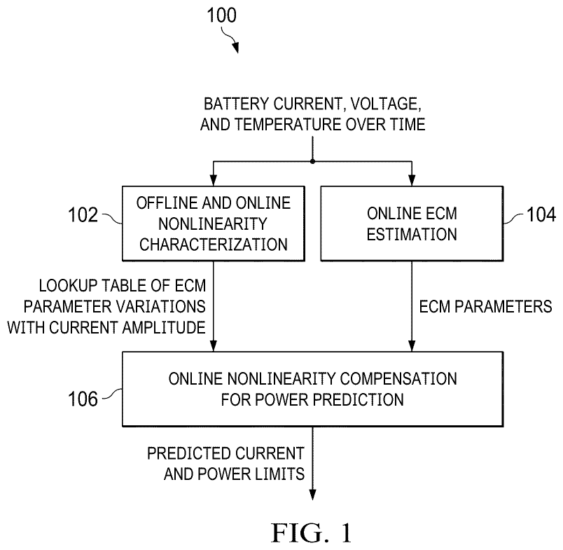

FIG. 1 illustrates a block diagram of an example battery dynamic power prediction system 100 that may include a nonlinear ECM and offline and online nonlinearity characterization 102 along with online ECM estimation 104 and nonlinearity compensation 106, in accordance with embodiments of the present disclosure. The combination of a nonlinear ECM and offline and online nonlinearity characterization 102 with online ECM estimation 104 and nonlinearity compensation 106 may provide a systematic way to address battery nonlinearity for accurate power prediction.

System 100 may utilize measurements of battery load current, terminal voltage, and temperature over time, as well as estimates of battery capacity and SOC over time (e.g., obtained using a coulomb counter). System 100 may also use a battery OCV-SOC table.

Approaches to obtaining such measurements, estimates, and OCV-SOC table are known, and such approaches may be utilized for embodiments of this disclosure.

The discussion below begins with a description of the nonlinear ECMs in accordance with embodiments of the present disclosure.

An ECM describes a battery's voltage response for an applied load current, as governed by the OCV and its impedance.

A battery's impedance may be affected by many factors. A battery is typically nonlinear, as its impedance may vary significantly with load current amplitude, especially at low temperatures (the physics of the charge transfer process is given by the BV relationship). The impedance may also change significantly with SOC (e.g., in a bathtub-like curve), temperature (e.g., in accordance with the Arrhenius law), and age. Thus, an ECM may need to have sufficient flexibility to be able to model the impedance well over a wide range of operating conditions.

As mentioned above, two different nonlinear ECMs are contemplated in this disclosure. The first is a nonlinear RC ECM with fixed, logarithmically spaced RC time constants and adjustable resistances subject to a nonnegativity constraint, which may adapt to the nonlinearity using current dependent RC resistances alone. The second is a physics-based nonlinear fractional-order ECM comprised of current dependent ZARC elements, which may be better suited than the conventional RC ECM to address nonlinearity by keeping the current independent and dependent physics separate.

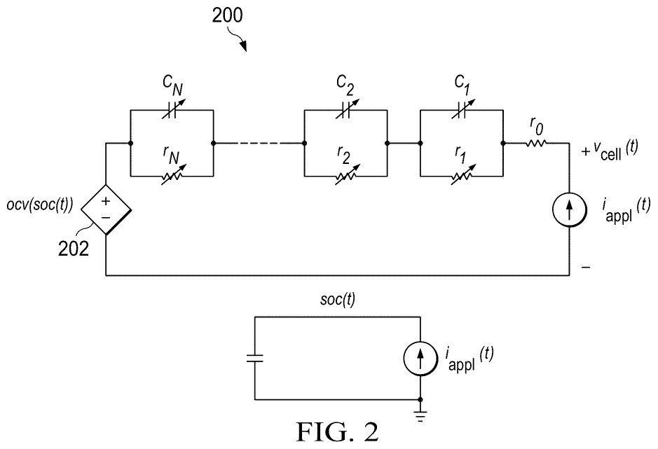

FIG. 2 illustrates an example nonlinear RC ECM 200 with an OCV (e.g., ocv(soc(t)) 202), a current independent series resistance r₀, and N current dependent RC resistances r₁, r₂, . . . , and r_{N} and capacitances c₁, c₂, . . . , c_{N}, in accordance with embodiments of the present disclosure. The series resistance may represent ohmic effects, and the RC elements may capture the time constants of underlying physical processes, such as the charge transfer reaction and diffusion of lithium in the electrode and electrolyte. Optionally, in some embodiments, ECM 200 might also include a series inductor, a series capacitor, and resistor-inductor (RL) elements (not shown in FIG. 2).

At time t, the terminal voltage v_{cell}(t) may be expressed as:

$${v}_{cell} ( t ) = ocv ( soc ( t ) ) + {i}_{appl} ( t ) {r}_{0} + {\sum }_{n = 1}^{N} {i}_{n} ( t ) {r}_{n} , \qquad ( 1 )$$

where ocv(soc(t)) is the OCV, soc(t) is the SOC, iₐₚₚₗ(t) is the applied load current, iₙ(t) is the nth RC current. Here the current is negative, indicating discharge for the battery.

The SOC may be defined by a coulomb count:

$$soc ( t ) = soc ( {t}_{0} ) + \frac{1}{Q} {\int }_{{t}_{0}}^{t} {i}_{appl} ( {t}^{′} ) {dt}^{′} ,$$

where Q denotes the battery capacity.

In frequency domain, RC ECM 200 may model battery impedance as:

$${z}_{R C} ( j ω ) = {r}_{0} + {\sum }_{n = 1}^{N} \frac{{r}_{n}}{1 + j {ωτ}_{n}} ,$$

where j is the imaginary unit equal to the square root of −1, ω is angular frequency and is the nth RC time constant.

$${τ}_{n} = {r}_{n} {c}_{n} , n = 1 , … , N , \qquad ( 3 )$$

RC ECM 200 satisfies the Kronig-Kramers Transform (KKT) conditions, and may be viewed as a stable, causal, rational approximation of the battery impedance transfer function.

For discrete-time simulation, the RC system may be discretized using the bilinear transform and the RC currents may be given by:

$${i}_{n} [ m ] = - {a}_{n , 1} {i}_{n} [ m - 1 ] + {b}_{n , 0} {i}_{appl} [ m ] + {b}_{n , 1} {i}_{appl} [ m - 1 ] , \qquad ( 4 )$$

where m denotes discrete time and the various coefficients in equation (4) are given by:

$${a}_{n , 1} = \frac{1 - 2 {τ}_{n} / Δ t}{1 + 2 {τ}_{n} / Δ t} ,$$

$${b}_{n , 0} = {b}_{n , 1} = \frac{1}{1 + 2 {τ}_{n} / Δ t} ,$$

with Δt denoting the sampling period. Using zero-order hold, the SOC may be discretized as:

$$soc [ m ] = soc [ {m}_{0} ] + \frac{Δ t}{Q} {\sum }_{{m}^{′} = {m}_{0}}^{m - 1} {i}_{appl} [ {m}^{′} ] .$$

The ECM resistances and RC time constants are free parameters of the model that may be optimized to fit the data. Adjusting both the resistances and RC time constants of ECM 200 may allow for potentially better modeling of the impedance over a wide range of operating conditions. Also, a smaller model order may be needed. However, this RC ECM parameter estimation problem requires nonlinear optimization, which is expensive to implement in time-domain at a high sampling rate. Traditional approaches have investigated low-order RC ECM estimation using a simpler linear approach based on recursive least-squares (RLS) minimization of the equation error. However, due to the weighting of the error, the equation error method is known to give biased estimates. In another approach, joint and dual state and RC ECM parameter estimation was performed using the extended and sigma-point Kalman filters. In this approach, special care is needed to ensure that the state and parameter estimates converge to physically meaningful values. It should be noted that RLS and Kalman filters often require stabilized implementations for numerical robustness.

Fixing the RC time constants and only adjusting the resistances of the ECM considerably simplifies the estimation process because the RC ECM parameter estimation problem then becomes linear. In particular, the output error has a global minimum, may be minimized using linear estimation techniques, and the estimates may be unbiased. A larger model order is generally needed compared to the ECM with adjustable time constants, but the estimation cost may remain lower. It is noted that when the RC time constants are fixed, only the ECM resistances are free parameters of the model, and the RC capacitances are implicit from equation (3).

The internal processes of a battery span a broad range of time scales, e.g., from micro-seconds to hours. In accordance with embodiments of the present disclosure, RC ECM 200 may include adjustable resistances and fixed, logarithmically spaced RC time constants:

$${τ}_{n} = 1 {0}^{{log}_{10} {τ}_{min} + \frac{n - 1}{N - 1} ( {log}_{10} τ - {log}_{10} {τ}_{min} )} , n = 1 , … , N .$$

Absent some prior knowledge, uniformly spacing the time constants in the log τ domain favors no particular values of time constants over others.

The range of RC time constants should be selected to include the prediction time horizons of interest for power prediction. For example, assuming prediction horizons from a minimum time tₘᵢₙ to a maximum time tₘₐₓ, and taking an extra logarithmic decade on each side, the RC time constants may be logarithmically spaced over the range τₘᵢₙ=0.1tₘᵢₙ to τₘₐₓ=10tₘₐₓ. A large range of RC time constants allows for modeling of the battery impedance over a wide frequency range.

From identifiability conditions, the smallest RC time constant that may be estimated is governed by the sampling frequency (e.g., should be greater than ˜0.25 times the sampling period), and the largest RC time constant that may be estimated is governed by the data duration (generally limited to some small factor times the data duration).

The number of RC elements N may be selected on a points-per-decade basis. It should be large enough to allow sufficient flexibility in modeling the impedance well over a wide range of operating conditions, but not so large that the estimation problem becomes ill-conditioned. A large model order also entails higher computational cost.

It is noted that use of a small number of fixed, “tuned” RC time constants may result in inconsistent performance (the time constants of a battery may vary significantly with operating conditions of current amplitude, SOC, temperature, and age, and the ECM may not generalize well between scenarios).

In a prior art approach, an RC ECM with logarithmically spaced RC time constants and adjustable resistances was used for designing a KKT condition test. No constraint was applied on the ECM resistances, and it was observed that the resistances show alternating sign changes with cancelling contributions.

In accordance with the present disclosure, the adjustable resistances of RC ECM 200 may be constrained to be nonnegative:

rₙ≥0,n=1, . . . ,N.

Constraining the resistances to be nonnegative may avoid the cancelling contributions problem and may have the desirable effect of automatically forcing the RC resistances associated with any unneeded RC time constants to zero. Thus, even though the RC time constants may be fixed to a logarithmically spaced set, the resistances may be adjusted such that RC ECM 200 may emphasize or de-emphasize time constants adaptively as needed to achieve good modeling over a wide range of operating conditions of current amplitude, SOC, temperature, and age. With the nonnegativity constraint and sufficiently large N, the resulting resistances may be interpreted as a Distribution of Relaxation Times (DRT). Additionally, the nonnegativity constraint on the ECM resistances may also reduce spurious solutions and has a regularizing effect on the estimation problem. In the existing art, the nonnegativity constraint has also been motivated based on the passivity condition.

It is noted that in general the RC ECM resistances do not have a physical meaning—their role is simply to aid in modeling the battery's impedance which ultimately governs the voltage response.

It has been long known that the physics of many electrochemical systems may be described by fractional-order circuit elements. This fractional-order/distributed circuit element behavior arises due to distributed microscopic material properties, SEI surface defects, local inhomogeneities, variations in stoichiometry, surface reactivity and particle geometry, and a continuous distribution of time constants is observed in practice. Therefore, in circuit representations, ideal capacitors are often replaced by fractional capacitors. Some examples of fractional-order circuit elements include constant-phase elements (CPEs), ZARC and YARC elements, and the Warburg impedance.

A battery's measured EIS impedance, which resembles a series of depressed arcs in the Nyquist plane, may be modeled succinctly using an ECM with a few ZARC elements (depressed arcs in the Nyquist plane) as opposed to many RC elements (semi-circles in the Nyquist plane).

In one prior art approach, a closed-form impedance model for lithium-ion batteries was developed based on the P2D model. The model included a circuit model for the SEI and has been recently expanded with CPEs. In some other works, ECMs with ZARC and Warburg elements were used for battery management. In another approach, a single particle model (SPM) based nonlinear fractional-order impedance model for lithium-ion batteries was developed. The ECM includes ZARC elements for modeling diffusion and surface stoichiometry and current dependent charge transfer resistances based on the BV relation but does not include double-layer capacitances.

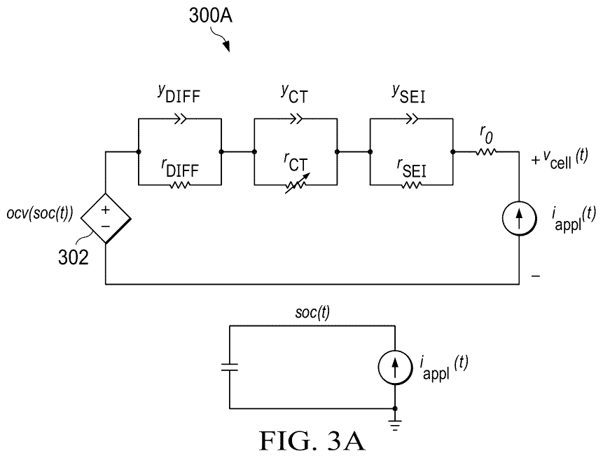

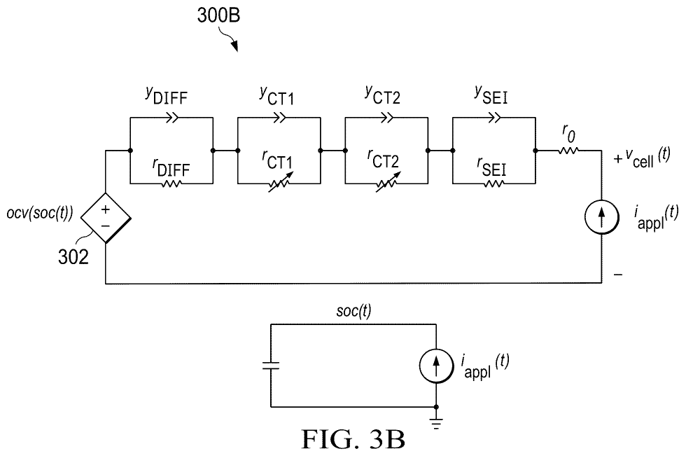

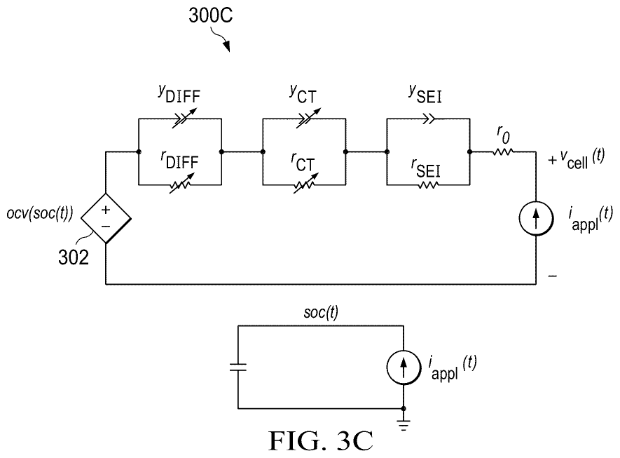

FIG. 3A illustrates an example physics-based nonlinear fractional-order ECM 300A with an OCV 302, current independent series resistance r₀, an SEI ZARC element, a diffusion ZARC element, and a current dependent charge transfer ZARC element, in accordance with embodiments of the present disclosure. ECM 300A may be based on the SPM and may utilize current independent and dependent model portions comprising the OCV and several ZARC elements. The current independent model portion of the ECM may comprise series resistance r₀ and ZARC elements that capture the response of the film-electrolyte interface (SEI ZARC element) and diffusion of reactants and/or products to the interface (diffusion ZARC element). The film here refers to the SEI film. The current dependent model portion of the ECM may include a ZARC element that captures the response of a charge transfer process at the solid-film interface via a current dependent charge transfer resistance (charge transfer ZARC element). Optionally, in some embodiments, ECM 300A may include a series inductor, a series capacitor, and RL elements (not shown in FIG. 3A).

In frequency domain, fractional-order ECM 300A may model the battery impedance as:

$${z}_{Z A R C} ( j ω ) = {r}_{0} + \frac{{r}_{S E I}}{1 + {( j {ωτ}_{S E I} )}^{{ϕ}_{S E I}}} + \frac{{r}_{C T}}{1 + {( j {ωτ}_{C T} )}^{{ϕ}_{C T}}} + \frac{{r}_{D I F F}}{1 + {( j {ωτ}_{D I F F} )}^{{ϕ}_{D I F F}}} , \qquad ( 5 )$$

where r_{SEI}, τ_{SEI}, φ_{SEI} are the resistance, time constant, and exponent parameters, respectively, of the SEI ZARC element, r_{CT}, τ_{CT}, φ_{CT} are the resistance, time constant, and exponent parameters, respectively, of the charge transfer ZARC element, and r_{DIFF}, τ_{DIFF}, φ_{DIFF} are the resistance, time constant, and exponent parameters, respectively, of the diffusion ZARC element, with the time constants given by:

$${τ}_{S E I} = {( {r}_{S E I} {y}_{S E I} )}^{1 / {ϕ}_{S E I}} ,$$

$${τ}_{C T} = {( {r}_{C T} {y}_{C T} )}^{1 / {ϕ}_{C T}} ,$$

$${τ}_{D I F F} = {( {r}_{D I F F} {y}_{D I F F} )}^{1 / {ϕ}_{D I F F}} ,$$

where Y_{SEI}, Y_{CT}, Y_{DIFF} are the CPEs of the SEI, charge transfer and diffusion ZARC elements, respectively, with the current dependency of the charge transfer resistance suppressed for clarity. It is noted that a ZARC element generally does not represent a single time constant but rather a distribution of time constants.

Model 300A may use a linearized diffusion overpotential. This linearized diffusion overpotential may simplify the estimation process and may not require knowledge of the OCV curve beyond SOC=0% and SOC=100% because OCV lookups may use equilibrium SOC instead of surface SOC, at the expense of some reduction in accuracy.

Physics-based nonlinear fractional-order ECM 300A may succinctly model the battery impedance as governed by electrochemistry. A key benefit of nonlinear fractional-order ECM 300A is that it may resolve and keep the current independent and dependent physics separate, whereas unrelated dynamics may be blended in nonlinear RC ECM 200 (e.g., depending on the time constant overlap). Thus, nonlinear fractional-order ECM 300A may be a better model of battery dynamics, including nonlinearity, and may yield better power prediction performance. The drawback is that estimation and simulation of fractional-order ECM 300A may be significantly more complex and expensive compared to RC ECM 200.

Other physics-based nonlinear fractional-order ECMs with multiple current dependent parameters are contemplated in accordance with embodiments of the present disclosure. These ECMs may be more suitable models in some scenarios. For example, FIG. 3B illustrates an example physics-based nonlinear fractional-order ECM 300B with an OCV 302, current independent series resistance r₀, an SEI ZARC element (e.g., that may capture a response of the film-electrolyte interface), and a diffusion ZARC element (e.g., that may capture a response of the diffusion of reactants and/or products to the interface), and two current dependent charge transfer ZARC elements (e.g., that may capture the response of a charge transfer process at the solid-film interface), in accordance with embodiments of the present disclosure. Optionally, in some embodiments, ECM 300B may include a series inductor, a series capacitor, and RL elements (not shown in FIG. 3B).

As another example, FIG. 3C illustrates an example physics-based nonlinear fractional-order ECM 300C with an OCV 302, current independent series resistance r₀ and SEI ZARC element, and current dependent diffusion ZARC element and charge transfer ZARC element, in accordance with embodiments of the present disclosure. ECM 300C may be similar in many respects to ECM 300A, except that ECM 300C may include, e.g., current dependent CPEs y_{CT} and Y_{DIFF} and current dependent resistance r_{DIFF}, which are fixed in ECM 300A. Optionally, in some embodiments, ECM 300C may include a series inductor, a series capacitor, and RL elements (not shown in FIG. 3C).

Techniques for simulation of fractional-order systems include, for example, Oustaloup's method using integer-order transfer functions, Grunwald-Letnikov fractional derivative approximations, and ZARC element approximation by a series of RC elements using semi-analytical expressions. Another technique may include accurate approximations of the ZARC elements by series of RC elements calculated using Vector Fitting (VF) in order to simulate ECMs 300A, 300B, and/or 300C.

Described next are the offline and online nonlinearity characterization procedure in accordance with embodiments of the present disclosure.

As described above, a battery's response may be nonlinear, as its impedance may vary significantly with load current amplitude, especially at low temperatures. The battery's nonlinearity must be characterized for accurate prediction of the available power.

While the battery is nonlinear, it may be linearized at a given operating set point of current amplitude, and the best linear approximation may be a reasonably good model for that current amplitude set point. Thus, the nonlinearity of a battery may be characterized based on its current dependent impedance.

In accordance with this disclosure, nonlinearity characterization (e.g., offline and online nonlinearity characterization 102) may use broadband pulse load currents of various amplitudes to determine the current dependent battery impedance for various respective current amplitudes, SOCs, temperatures, and ages. Use of a broadband excitation may aid in accurate estimation of the battery impedance over a wide range of frequencies. The broadband pulse load currents may include uniform random white noise of various mean amplitudes. The peak-to-peak variation of these broadband pulse load currents may be selected to achieve acceptable signal-to-noise ratio for all frequencies while remaining close to the amplitude set point of interest.

The current dependent battery impedance may be fitted by a nonlinear ECM using least-squares optimization. In the fitting process, the current independent parameters of the ECM may be kept at their low current values. To further improve the consistency of the fitting, the optimization may be performed jointly across current amplitudes, SOCs and temperatures with constraints on the ECM parameter variations. A lookup table of ECM parameter variations with current amplitude for various operating set points (shown as being output by offline and online nonlinearity characterization 102 in FIG. 1) may be created and maintained.

For offline nonlinearity characterization, first, load current and terminal voltage data may be collected by applying broadband pulse load currents to the battery for various current amplitudes, SOCs, and temperatures. To perform this characterization, the battery may be brought to a relaxed state at a desired SOC and temperature. Relaxation may be defined based on a small change in voltage with respect to time (small |dv/dt|). The battery temperature may be held constant, for example by using a Peltier device and thermal chamber.

A sequence of broadband pulse load currents of various amplitudes and durations may be applied to the battery, and the load current and corresponding terminal voltage may be recorded. The amplitudes of the pulses may be selected to span the range of interest for power prediction, with the amplitude steps selected such that the nonlinearity is adequately resolved. The duration of the pulses may be selected to balance various competing requirements: (a) low frequency resolution, (b) time horizons for which power prediction is needed, (c) minimizing risk of damage to the battery, and (d) SOC resolution (for accurate characterization, the SOC should be kept close to the desired SOC; the impedance may change rapidly at the very low or high SOCs).

After the application of each broadband pulse load, the battery may be charged and brought back to a relaxed state at the desired SOC. The foregoing characterization may be repeated for various SOCs and temperatures.

The offline nonlinearity characterization data may be collected from new batteries. If cell-to-cell variability is low, the characterization results may be averaged. The offline nonlinearity characterization data may also be collected from batteries aged to various states-of-health (SOHs) using cycling experiments.

Next, the current dependent battery impedance may be modeled over a range of frequencies parametrically using a nonlinear ECM and estimated using the collected load current and terminal voltage data for the various current amplitudes, SOCs, temperatures, and ages. Specifically, the impedance at each current amplitude set point may be modeled and estimated parametrically by fitting an ECM.

For example, an RC ECM (e.g., ECM 200) with fixed, logarithmically spaced RC time constants and adjustable nonnegative resistances may be utilized. With the RC time constants fixed and only the resistances of the ECM optimized, the RC ECM may be fitted to the measured data by minimizing the output error using linear estimation techniques.

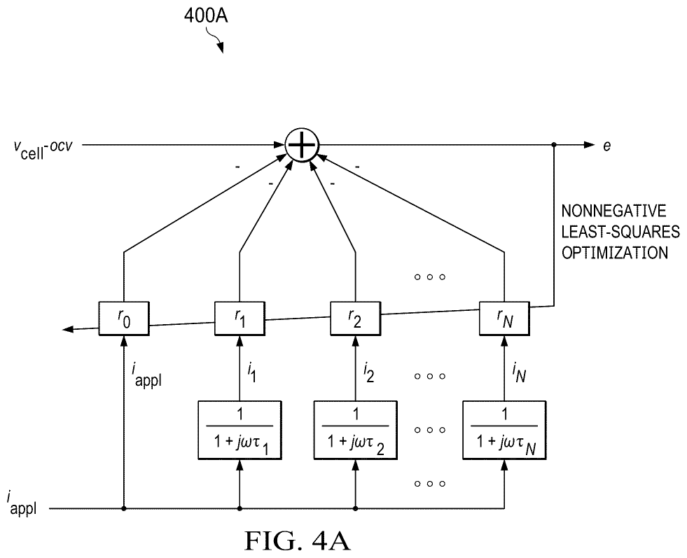

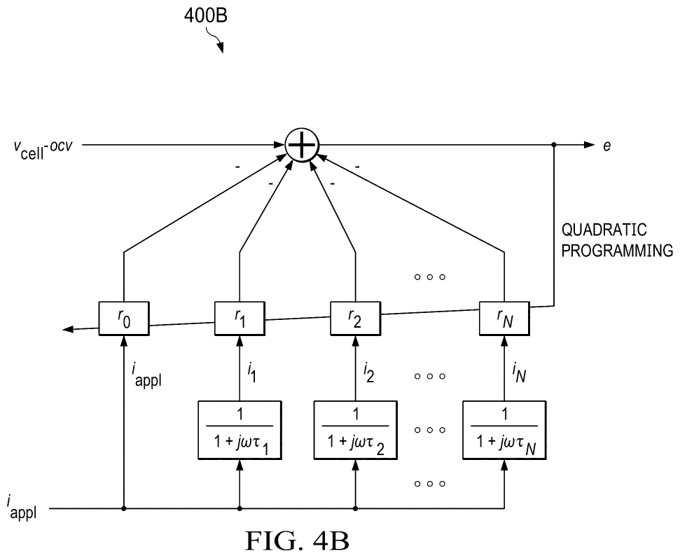

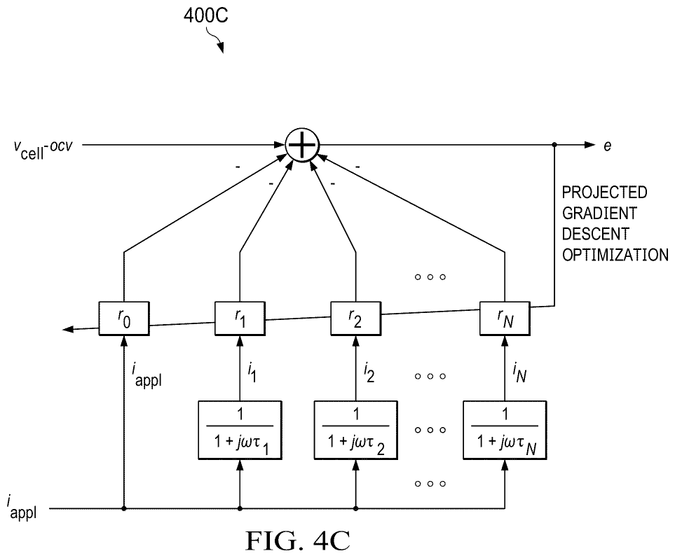

FIG. 4A illustrates a block diagram of an example architecture 400A that may be used for RC ECM fitting in the offline nonlinearity characterization, in accordance with embodiments of the present disclosure. The applied current and RC currents may be used as reference signals along with the debiased (i.e., OCV removed) terminal voltages as the desired signals, and the resistances may be optimized subject to a nonnegativity constraint such that the difference between the measured voltage and the voltage predicted by the model is minimized. The RC currents may be calculated using the applied current and the RC time constants in accordance with equation (4). Zero initial conditions may be used because the battery may be in a relaxed state at the start of the broadband pulse. In some embodiments, the OCV may also be treated as unknown and estimated jointly along with the ECM resistances.

A reference signal vector u[m] at time m may be defined using the applied and RC currents as:

$$u [ m ] = {[ {i}_{appl} [ m ] {i}_{1} [ m ] … {i}_{N} [ m ] ]}^{T} ,$$

where the superscript^{T} denotes transpose, and the desired signal d[m] at time m may be defined using the terminal voltage and OCV as:

$$d [ m ] = {v}_{cell} [ m ] - o c v ( s o c [ m ] ) .$$

A reference signal data matrix U may be defined as:

$$U = {[ u [ 1 ] u [ 2 ] … U [ M ] ]}^{T} ,$$

with M the number of characterization data samples (with M>N+1), and the desired signal vector d may be defined as:

$$d = {[ d [ 1 ] d [ 2 ] … d [ M ] ]}^{T} .$$

The RC ECM voltage equation (1) may be expressed as:

$$d = U r + w ,$$

where r is a vector comprised of the ECM series resistance and RC resistances:

$$r = {[ {r}_{0} {r}_{1} … {r}_{N} ]}^{T} ,$$

and w denotes the noise in the voltage measurement. Here the noise in the voltage measurement has been assumed to be additive and the noise in the current measurement has been ignored.

Assuming further that the noise is white Gaussian, the best linear, unbiased estimator for r may be obtained by minimizing the sum squared error cost function (least-squares), subject to the aforementioned nonnegativity constraint:

$${r}^{*} = {arg min}_{r} {‖ Ur - d ‖}^{2} subject to r \geq 0. \qquad ( 6 )$$

Optionally, the cost function may include equal weighting of the error in each logarithmic decade.

The nonnegative least-squares problem of equation (6) is convex, and the objective function has a unique global minimum. If the reference signal data matrix U is full-rank, then the solution is unique. However, in practice, the reference signal data matrix U may be highly ill-conditioned, depending on the number of RC elements and RC time constants used, and reference signal spectral content. It is noted that the applied current here may be broadband and therefore may have sufficient spectral content.

Regularization may be applied to improve the conditioning of the problem. In Tikhonov regularization, a 2-norm penalty function is added to the cost function. The optimization in equation (6) is then modified to:

$${r}^{*} = {arg min}_{r} {‖ Ur - d ‖}^{2} + δ {‖ r ‖}^{2} \qquad ( 7 )$$

$$subject to r \geq 0 ,$$

where δ>0 denotes the regularization parameter. The regularization parameter may be selected using the L-curve method to make a tradeoff between the voltage fit error and the magnitude of the resistances, or using the discrepancy principle if the voltage measurement noise level is known. In some embodiments, the penalty term in equation (7) may be generalized to include a regularization matrix. To further improve the conditioning of the system, the largest RC time constant may be limited to a small factor times the data duration. Such limiting may be implemented by enforcing the associated RC resistances to be zero. Column scaling may also be applied to further improve the conditioning of the system.

Equation (7) may be readily solved using standard constrained linear least-squares optimization techniques, such as active-set or interior-point methods. After the fitting, the parametric estimate of the impedance may be available using the RC ECM impedance equation (2).

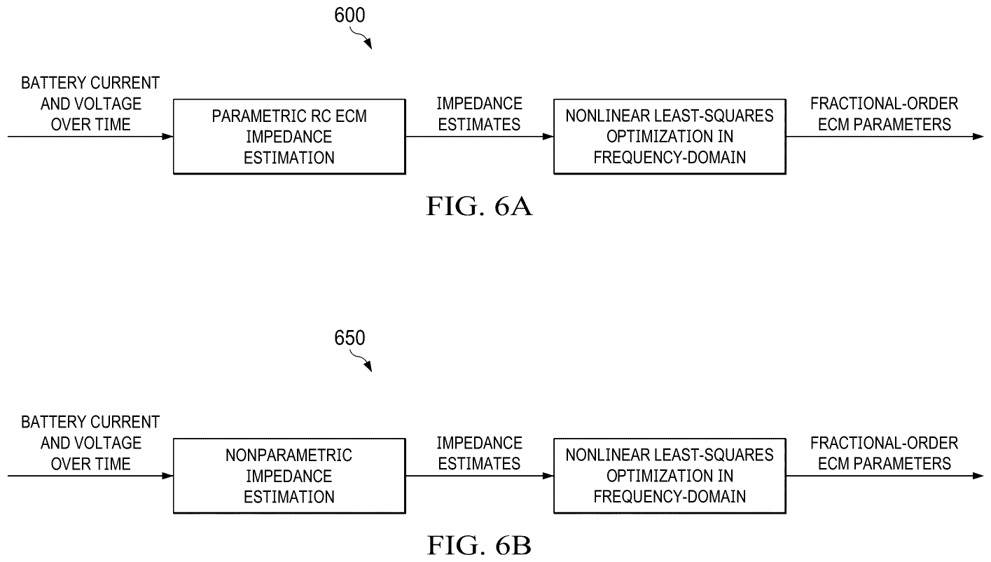

As discussed prior, a fractional-order ECM (e.g., ECM 300A, 300B, 300C) may also be used for parametrically modeling the current dependent impedance of the battery. The fractional-order ECM fitting may be carried out by leveraging the parametric RC ECM impedance estimate obtained above along with nonlinear least-squares optimization in frequency domain. FIG. 6A illustrates a block diagram of an example architecture 600 that may be used for the fractional-order ECM fitting in the offline and online nonlinearity characterization, in accordance with embodiments of the present disclosure.

Letting Ω={ω₁, ω₂, . . . ω_{K}} be a set of K logarithmically distributed frequency points:

$${ω}_{k} = 1 {0}^{{log}_{10} {ω}_{min} + \frac{k - 1}{K - 1} ( {log}_{10} {ω}_{max} - {log}_{10} {ω}_{min} )} , k = 1 , … , K . \qquad ( 8 )$$

The frequency range may be selected based on the time horizons of interest for power prediction. For example, assuming prediction horizons from tₘᵢₙ to tₘₐₓ, and taking an extra logarithmic decade on each side, the frequencies may be logarithmically spaced over the range: ωₘᵢₙ=0.1/tₘₐₓ to ωₘₐₓ=10/tₘᵢₙ. The number of frequency points K may be selected on a points-per-decade basis.

Letting impedance vectors be defined as:

$${z}_{RC} = {[ \begin{matrix}{z}_{RC} ( j {ω}_{1} ) & {z}_{RC} ( j {ω}_{2} ) & … & {z}_{RC} ( j {ω}_{K} )\end{matrix} ]}^{T} ,$$

where Z_{RC} (jωₖ) is the parametric RC ECM impedance estimate at frequency ωₖ, and

$${z}_{ZARC} ( θ ) = {[ \begin{matrix}{z}_{ZARC} ( j {ω}_{1} , θ ) & {z}_{ZARC} ( j {ω}_{2} , θ ) & … & {z}_{ZARC} ( j {ω}_{K} , θ )\end{matrix} ]}^{T} ,$$

where Z_{ZARC}(jωₖ) is the fractional-order ECM impedance of equation (5) evaluated at frequency ωₖ and:

θ={r₀,r_{SE1},τ_{SE1},r_{CT},τ_{CT},r_{DIFF},τ_{DIFF},φ_{DIFF}}

denotes a parameter set, comprised of the fractional-order ECM series resistance, and resistances, time constants, and exponents of the SEI, charge transfer, and diffusion ZARC elements. In some embodiments, the parameter set may include other ECM parameters, such as the ZARC element CPEs.

The fractional-order ECM may be fitted by minimizing the least-squares cost function:

$${θ}^{*} = {arg min}_{θ ∈ Θ} {‖ W ( {z}_{ZARC} ( θ ) - {z}_{RC} ) ‖}^{2}$$

using nonlinear optimization. Here W denotes an optional diagonal frequency weighting matrix. The ECM parameters may be constrained to reasonable ranges defined by the space Θ in the optimization. After the fitting, the parametric estimate of the impedance is available using the fractional-order ECM impedance equation (5). The procedure used for fitting the other fractional-order ECMs in accordance with embodiments of the present disclosure may be similar.

As described above, the battery nonlinearity may not follow the analytical single-particle BV curve exactly. In the methods and systems of the present disclosure, the battery nonlinearity may be captured using a lookup table, which may allow for a faithful representation of the measured battery nonlinearity without constraining it to any specific analytical model.

Specifically, offline and online nonlinearity characterization 102 may create a lookup table comprised of the ECM parameter variations with current amplitudes for various SOCs, temperatures, and ages. The parameters saved in the lookup table may include the series and RC resistances for RC ECM 200, and the charge transfer resistance for fractional-order ECM 300A. For the fractional-order ECMs with multiple current dependent parameters (e.g., ECMs 300B and 300C), the variations of all these parameters with current amplitudes for various SOCs, temperatures, and ages may be saved in the lookup table.

Additionally, a measure of nonlinearity may be calculated based on the ECM parameter variations with current amplitude for various SOCs, temperatures, and ages and saved in the lookup table.

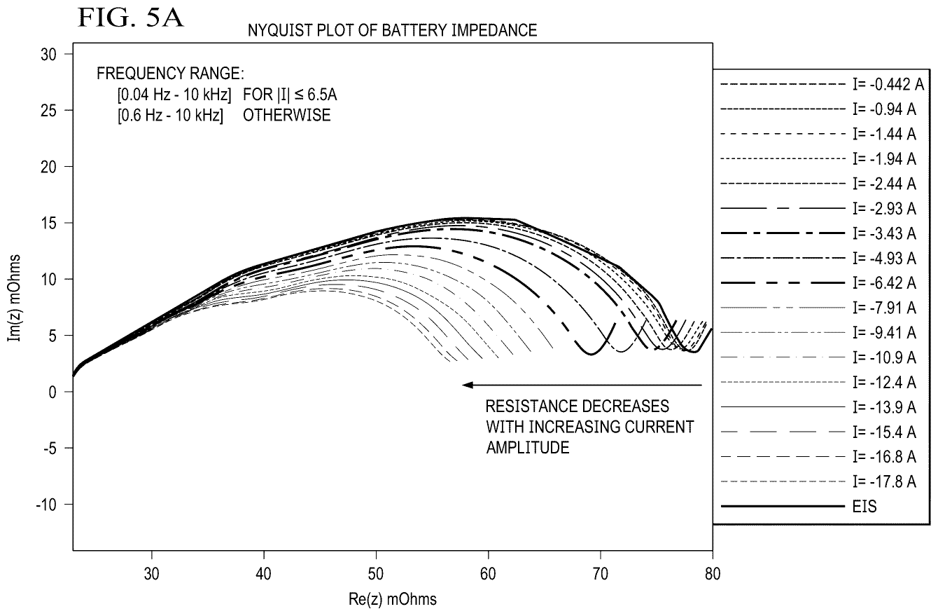

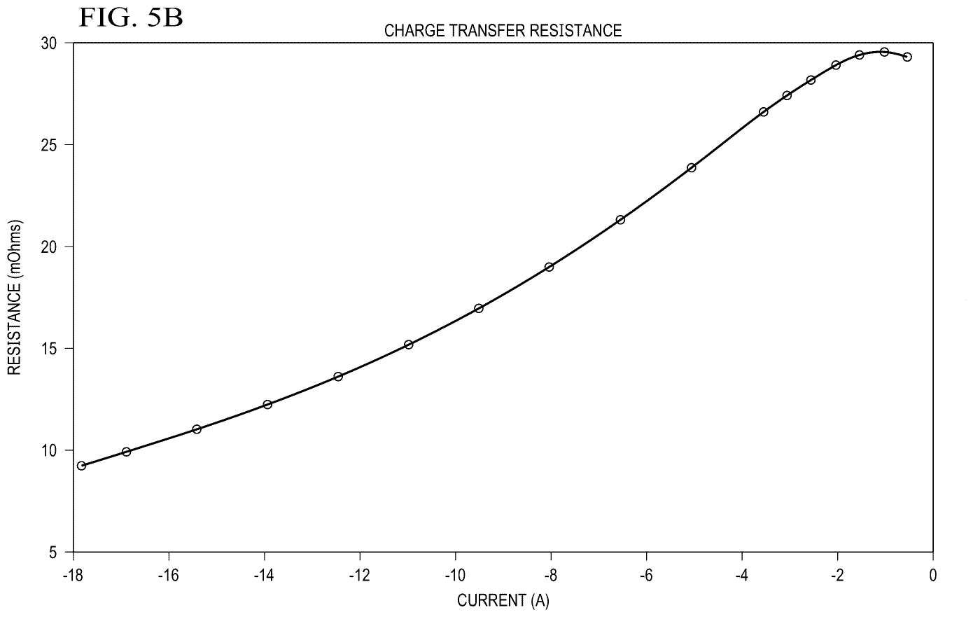

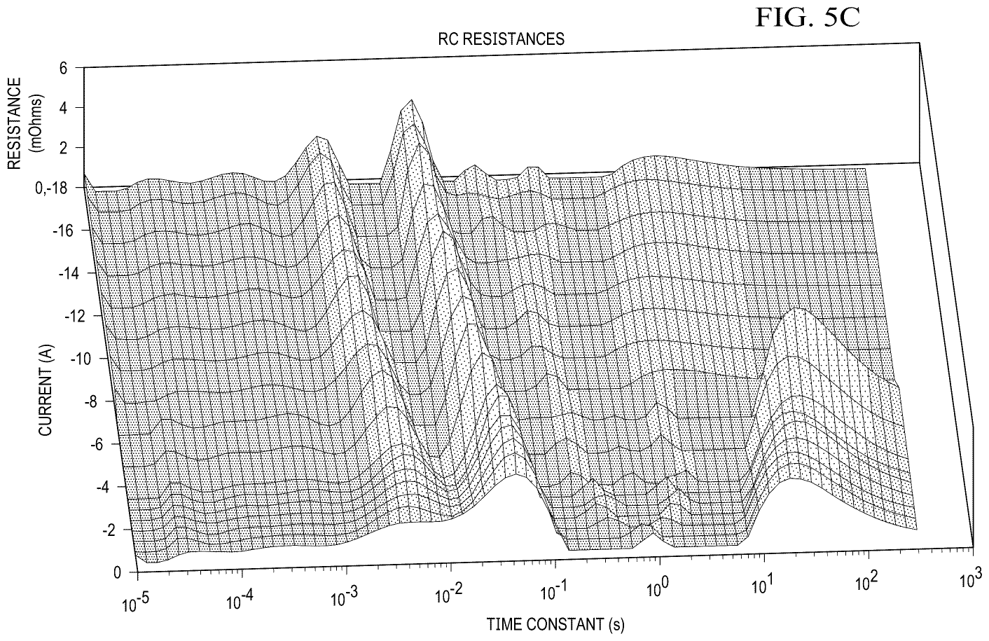

As an example result of the nonlinearity characterization procedure, FIG. 5A illustrates a plot of the impedance variation with current amplitude in a new lithium-ion battery at a SOC equal to 20% and temperature equal to 25° C., in accordance with embodiments of the present disclosure. Also shown for reference in FIG. 5A is impedance from an EIS measurement at the same SOC and temperature. The impedance is shown for a frequency range of 40 mHz to 10 kHz for EIS and current amplitudes less than or equal to 6.5 A, and 0.6 Hz to 10 kHz for the current amplitudes greater than 6.5 A. The frequency range may be different for low and high current amplitudes due to the use of different pulse durations (shorter duration pulses are used for high current amplitudes). Nonlinearity may be observed mainly in the low frequencies. The impedance may be current amplitude independent at high frequencies, e.g., above 100 Hz, and may be current amplitude dependent at the mid and low frequencies where the impedance decreases with increasing current amplitude.

FIG. 5B illustrates a plot of the nonlinear fractional-order ECM current dependent charge transfer resistance of a new lithium-ion battery at a SOC equal to 20% and temperature equal to 25° C., in accordance with embodiments of the present disclosure. It may be observed that, as expected from physics, the charge transfer resistance decreases with increasing current amplitude.

FIG. 5C illustrates a surface plot of the RC ECM current dependent RC resistances as a function of time constant and current amplitude for a new lithium-ion battery at a SOC equal to 20% and temperature equal to 25° C., in accordance with embodiments of the present disclosure. In FIG. 5C, the RC time constants are logarithmically spaced in the range: τₘᵢₙ=10 μs to τₘₐₓ=300 s. A large number (around 10) of points-per-decade were used in FIG. 5C, and the result may be interpreted as a DRT. It may be seen in FIG. 5C that the RC resistances show two prominent peaks in the charge transfer regime (with time constants ranging from a few milli-seconds to a hundred milli-seconds), that decrease in amplitude and shift toward smaller time constants as the current amplitude increases. This trend is consistent with two charge transfer resistances and (distributed) time constants that decrease with current amplitude as expected from physics. Another prominent peak is seen in the diffusion regime (with time constants near tens of seconds) for low current amplitudes. Note that large time constants may not be estimated for high current amplitudes (greater than 6.5 A) due to the use of short pulse durations. One or two weaker and broader peaks are also observed at time constants near 100 μs. The presence of around three to four DRT peaks is why a compact representation of the battery impedance may be obtained using the fractional-order ECMs with three to four ZARC elements (e.g., ECM 300A, 300B, or 300C).

The nonlinearity of the battery may need to be continuously characterized as the battery impedance changes (gradually) over time due to aging. Thus, online nonlinearity characterization may be performed using the measured load current and terminal voltage of the battery during normal operation, as described below.

In online nonlinearity characterization, the broadband pulse load currents of various amplitudes and durations may be applied online by augmenting to the normal dynamic load of the battery using dedicated hardware. Additionally, if currents of the desired amplitudes and durations are detected in the normal dynamic load, they may be utilized for online nonlinearity characterization.

The online augmentation may be performed only when a certain minimum amount of difference is detected between the present and last estimated low-current impedance at the operating SOC and temperature stored in the lookup table. The decision to perform online augmentation may additionally be informed by the nonlinearity measure stored in the lookup table.

Safeguards may be applied to the pulse amplitudes and durations used to prevent the characterization pulses from causing system brownout.

The dynamic load level when an online nonlinearity characterization is performed may also be recorded in the lookup table and may be used to further improve the nonlinearity compensation performance.

In single-cell systems, online nonlinearity characterization by augmentation of high-amplitude pulse discharge currents to the battery may be limited to infrequent pulses of short duration, because of energy constraints (a limit on how much of the battery's available energy may be discharged solely for the purpose of power prediction) and thermal limits (an amount of heat that may be safely dissipated on-chip or in the system that may be limited).

These limitations may render it difficult to precisely characterize low-frequency battery nonlinearity using online pulse augmentation during discharge, which may result in reduced power prediction performance for long time horizons.

While there may be interest in only characterizing discharge nonlinearity for power prediction, the systems and methods described herein may remain applicable for characterizing charge nonlinearity as well. Charge-discharge symmetry of the battery nonlinearity may be exploited to derive information about discharge nonlinearity from online nonlinearity characterization performed during charging. The advantage of performing online characterization during charging is that long duration augmentation pulses may be used to better characterize low-frequency battery nonlinearity, which may otherwise be difficult to do during discharge due to stringent energy and thermal limitations.

In multi-cell systems, online nonlinearity characterization may be performed by moving charge between cells. Ibis directly alleviates the above-mentioned energy and thermal limitations.

The current dependent battery impedance may be modeled parametrically using a nonlinear ECM and calculated using the augmented load current and measured terminal voltage for the various current amplitudes. For online characterization, the RC ECM fitting algorithm of equation (7) may be modified to reduce the memory requirement and computational complexity. FIG. 4B illustrates a block diagram of an example architecture 400B that may be used for RC ECM fitting in the online nonlinearity characterization, in accordance with embodiments of the present disclosure. In some embodiments, the OCV may also be treated as unknown and estimated jointly along with the ECM resistances.

As before with offline nonlinearity characterization, the RC currents may be calculated using the applied current and the RC time constants in accordance with equation (4). The initial conditions may not be zero for online characterization, because the battery may not be in a relaxed state at the start of the broadband pulses.

A reference signal autocorrelation matrix Rᵤᵤ and reference and desired signal cross-correlation vector p_{ud} may be defined as:

$${R}_{uu} = \frac{1}{M} {U}^{T} U = \frac{1}{M} {\sum }_{m = 1}^{M} u [ m ] {u}^{T} [ m ] ,$$

$${p}_{ud} = \frac{1}{M} {U}^{T} d = \frac{1}{M} {\sum }_{m = 1}^{M} u [ m ] d [ m ] .$$

The autocorrelation matrix Rᵤᵤ is symmetric and positive semidefinite (positive definite if U is full-rank). The optimization of equation (7) may be rewritten as:

$${r}^{*} = {arg min}_{r} {r}^{T} {R}_{uu} r - 2 {p}_{ud}^{T} r + δ {‖ r ‖}^{2}$$

$$subject to r \geq 0 ,$$

which may be solved efficiently using standard quadratic programming methods.

Rᵤᵤ and p_{ud} may be calculated without forming the matrix U and vector d, substantially reducing the memory requirement. However, the use of the normal equations may result in a significant increase in the condition number: K(Rᵤᵤ)=K(U)².

The lookup table of ECM parameter variations over current amplitudes, SOCs, and temperatures may be continuously updated based on the current dependent impedance estimated in the online nonlinearity characterization. After each online current dependent impedance estimate, the ECM parameters in the lookup table for the augmented load current amplitude and operating SOC and temperature may be updated based on the new estimates.

Because aging generally occurs gradually over time, the online augmentation and lookup table updates do not have to be performed very frequently. The creation and maintenance of a lookup table may be crucial for eliminating the need for frequent online augmentation of high-current pulses, and may also reduce the risk of adversely affecting the health of the battery.

The online ECM estimation method is now described in accordance with embodiments of the present disclosure.

The battery impedance may change as a function of current amplitude, SOC, temperature, and age, and the ECM must continuously be adapted to track this time-varying system. Online ECM parameter estimation 104 may be performed using the measured load current and terminal voltage of the battery during normal operation.

In accordance with the systems and methods disclosed herein, the RC ECM 200 with fixed, logarithmically spaced RC time constants and nonnegative resistances may be estimated online using the measured battery load current and terminal voltage over time efficiently via projected gradient descent optimization.

A major advantage of gradient descent is its lower computational cost compared to least-squares based methods, which may make it more suitable for efficient online implementation. At each time step, the solution is updated in the direction of the negative gradient of the cost function, and no Hessian or autocorrelation inversion may be needed. Another important advantage of gradient descent may be implicit regularization. For example, it has been shown that, for a rank-deficient reference signal autocorrelation matrix, gradient descent converges to a solution comprised of an orthogonal projection of the initialized value and the minimum-norm solution. This minimum-norm regularization may improve the robustness of the solution to ill-conditioning of the reference signal autocorrelation matrix. The main drawback of gradient descent lies in its slow convergence speed for ill-conditioned reference signal autocorrelation matrices, which may limit tracking performance in highly dynamic conditions. Some fast and efficient gradient methods exist in the prior art, but their error convergence is non-monotone.

In the present disclosure, a relaxed steepest descent method (stochastic gradient descent) may be used with exponentially averaged correlation estimates and optimum step-size, and gradient projection for efficiently estimating the resistances of RC ECM 200 online. FIG. 4C illustrates a block diagram of an example architecture 400C that may be used for online RC ECM estimation, in accordance with embodiments of the present disclosure. In some embodiments, the OCV may also be treated as unknown and estimated jointly along with the ECM resistances. The RC time constants used in online ECM estimation may be the same as those used for the nonlinearity characterization.

Letting r[m] denote the RC ECM resistance vector at time m, given by:

$$r [ m ] = {[ \begin{matrix}{r}_{0} [ m ] & {r}_{1} [ m ] & … & {r}_{N} [ m ]\end{matrix} ]}^{T} ,$$

where the time-dependence of the ECM resistances has been made explicit. The ECM resistances may be adapted to minimize a cost function J(r), defined at time m by the exponentially weighted m error:

$$J ( r ) = ( 1 - λ ) {\sum }_{{m}^{′} = 1}^{m} {λ}^{m - {m}^{′}} {e}^{2} [ {m}^{′} ] ,$$

where the error e[m′] is defined as:

$$e [ {m}^{′} ] = d [ {m}^{′} ] - {u}^{T} [ {m}^{′} ] r ,$$

and 0<λ<1 is the forgetting-factor that determines the time constant of the exponential average:

$$λ = exp ( - \frac{Δ t}{τ} ) .$$

The exponential averaging time constant may define the time support of the data used to update the ECM resistances and may be selected based on the rate of variation of the battery impedance with changing SOC, temperature, age, and non-stationary dynamic load.

In some embodiments, the cost function J(r) may include a regularization term that penalizes the 2-norm of the resistance vector r.

The cost function J(r) may be rewritten as:

$$J ( r ) = {r}^{T} {R}_{uu} [ m ] r - 2 {p}_{ud}^{T} [ m ] r + {σ}_{d}^{2} [ m ] ,$$

where Rᵤᵤ[m], P_{ud}[m], and σ_{d}²[m] denote the reference signal autocorrelation matrix, the reference and desired signal cross-correlation vector, and the desired signal power, respectively, at time m, defined by the exponential averages:

$${R}_{uu} [ m ] = ( 1 - λ ) {\sum }_{{m}^{′} = 1}^{m} {λ}^{m - {m}^{′}} u [ {m}^{′} ] {u}^{T} [ {m}^{′} ] ,$$

$${p}_{ud} [ m ] = ( 1 - λ ) {\sum }_{{m}^{′} = 1}^{m} {λ}^{m - {m}^{′}} u [ {m}^{′} ] d [ {m}^{′} ] ,$$

$${σ}_{d}^{2} [ m ] = ( 1 - λ ) {\sum }_{{m}^{′} = 1}^{m} {λ}^{m - {m}^{′}} {d}^{2} [ {m}^{′} ] .$$

The autocorrelation matrix Rᵤᵤ[m] is symmetric and positive semidefinite.

The cost function J(r) may be minimized using the relaxed steepest descent method. Specifically, at time m, the resistances may be updated by taking a step in the direction of the negative gradient:

$$r [ m + 1 ] = r [ m ] - α \frac{1}{2} μ [ m ] g [ m ] , \qquad ( 9 )$$

where g[m]≡g(r[m]) with the gradient g(r) of the cost function given by:

$$g ( r ) = 2 ( {R}_{uu} [ m ] r - {p}_{ud} [ m ] ) ,$$

and μ[m] is the optimum step-size from exact line search:

$$μ [ m ] = \frac{{g}^{T} [ m ] g [ m ]}{{g}^{T} [ m ] {R}_{u u} [ m ] g [ m ]} ,$$

and 0<α<2 is the relaxation parameter.

The update may be performed efficiently by calculating Rᵤᵤ and p_{ud} recursively

$${R}_{u u} [ m ] = λ {R}_{u u} [ m - 1 ] + ( 1 - λ ) u [ m ] {u}^{T} [ m ] ,$$

$${p}_{u d} [ m ] = λ {p}_{u d} [ m - 1 ] + ( 1 - λ ) u [ m ] d [ m ] .$$

The optimum step-size is an inverse Rayleigh quotient, and is bounded by the eigenvalues of Rᵤᵤ[m] as:

$$\frac{1}{{λ}_{max} ( {R}_{u u} [ m ] )} \leq μ [ m ] \leq \frac{1}{{λ}_{min} ( {R}_{u u} [ m ] )} .$$

Regularization may be applied to limit large steps:

$$μ [ m ] = \frac{{g}^{T} [ m ] g [ m ]}{{g}^{T} [ m ] {R}_{u u} [ m ] g [ m ] + δ} ,$$

where δ>0 denotes the regularization parameter.

The projected gradient method may be used to constrain the ECM resistances to be nonnegative. That is, after each steepest descent update in accordance with equation (9), the solution may be projected back to the closed point within the feasible set:

$$r [ m + 1 ] = max ( r [ m + 1 ] , 0 ) ,$$

where the maximum may be taken elementwise.

The resistances may be updated only when sufficient spectral content is present in the reference signal (i.e., when the load current is sufficiently above the measurement noise floor) and may be frozen under no-load (idle) conditions. To further improve efficiency, the online RC ECM resistance updates may be performed at a lower rate (at the expense of convergence speed and tracking capability).

In accordance with this disclosure, at least two different approaches may be used for online estimation of a fractional-order ECM (e.g., ECM 300A, 300B, 300C) by online ECM estimation 104. A first approach may be based on the parametric RC ECM impedance estimate that exhibits good convergence and tracking capability for impedance variations due to changes in current amplitude, SOC, or temperature. A second approach may use nonparametric impedance estimation and trades off some convergence speed at low frequencies for improvement in computational efficiency of the fractional-order ECM estimation.

To keep the computational cost low, the frequency-domain fractional-order ECM fitting may be carried out at a lower rate. In the nonlinear least-squares optimization, a warm start may be used to initialize the solver at each time step. The initial guess and bounds for the solution may be derived adaptively based on the estimate at the previous time. These enhancements further reduce the algorithm's computational cost (fewer pre-computations are performed, and fewer iterations are required for convergence) and improve its robustness.

FIG. 6A illustrates a block diagram of an example architecture 600 that may be used for the online fractional-order ECM estimation using a parametric impedance, in accordance with embodiments of the present disclosure. The online fractional-order ECM estimation may be carried out by leveraging the parametric RC ECM impedance obtained using the online RC ECM estimation algorithm above along with nonlinear least-squares optimization in frequency domain. The parametric RC ECM impedance computation may be carried out at a lower rate.

FIG. 6B illustrates a block diagram of an example architecture 650 that may be used for the online fractional-order ECM estimation using a nonparametric impedance, in accordance with embodiments of the present disclosure. The online fractional-order ECM estimation may be carried out by utilizing impedance estimates from nonparametric spectral analysis and Wiener filtering along with nonlinear least-squares optimization in frequency domain.

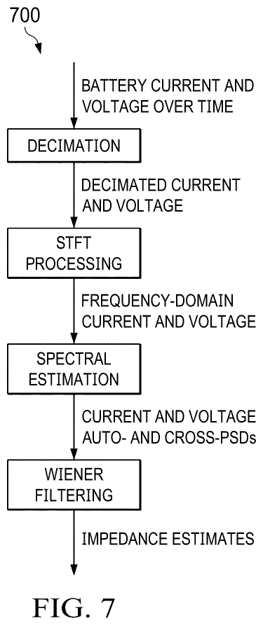

FIG. 7 illustrates a block diagram of an example architecture 700 that may be used for nonparametric impedance estimation, in accordance with embodiments of the present disclosure. In architecture 700, low frequencies may be processed at a lower rate to increase spectral resolution (for a given analysis window length) and reduce computational cost. For notational simplicity, in the approach described below, it is assumed that the terminal voltage has been de-biased by subtracting out the OCV.

The measured battery load current and terminal voltage over time may first be decimated by a set of factors {D₁, D₂, . . . , D_{C}}. Each of the decimated signals may then be processed using the short-time Fourier transform (STFT), to calculate the frequency-domain current and voltage signals:

$${i}_{c} [ l , s ] = {\sum }_{{l}^{′} = - ∞}^{∞} h [ lL - {l}^{′} ] {i}_{c} [ {l}^{′} ] {e}^{- j 2 π {sl}^{′} / S} ,$$

$${v}_{c} [ l , s ] = {\sum }_{{l}^{′} = - ∞}^{∞} h [ lL - {l}^{′} ] {v}_{c} [ {l}^{′} ] {e}^{- j 2 π {sl}^{′} / S} ,$$

where i_{c} and v_{c} are the current and voltage decimated by factor De, h is the analysis window, l denotes decimated time index, s denotes frequency index, L denotes the hop size, and S is the analysis window length.

The STFT may be calculated efficiently using the FFT and the weighted overlap-add structure. The analysis window may be chosen to achieve a good balance between high spectral resolution (narrow main lobe width) and low leakage (low side lobe level), and the analysis window length may be chosen to achieve sufficient spectral resolution at the low frequencies. The hop size may be chosen to balance computational cost and frequency-domain aliasing, and defines the rate of the frequency-domain signals (and ultimately the update rate of the impedance spectrum).

The decimation factors De may be selected such that the frequencies ω_{s,c}=2πs/SΔt_{c} include the set of desired impedance estimation frequencies Ω={ω₁, ω₂, . . . ω_{K}} defined in equation (8). Only the signals at these frequencies may be used for impedance estimation.

The minimum mean squared error optimum nonparametric impedance estimate may then be calculated using the Wiener filter:

$${z}_{W} ( j {ω}_{k} ) = \frac{{P}_{v i} [ k ]}{{P}_{i i} [ k ]} , \qquad ( 10 )$$

where Pᵢᵢ[k]=E[|i[k]|²] and Pᵥᵢ[k]=E[v[k]i*[k]] denote the current and voltage auto- and cross-power spectral densities (PSDs), respectively, at frequency ωₖ(E[·] denotes the expectation operator and the superscript * denotes complex conjugation). These PSDs may be estimated using the Welch method via a moving average:

$${P}_{i i} [ l , k ] = \frac{1}{{E}_{h} B} {\sum }_{{l}^{′} = l - B / 2 + 1}^{l + B / 2} {\vert i [ {l}^{′} , k ] \vert}^{2} ,$$

$${P}_{v i} [ l , k ] = \frac{1}{{E}_{h} B} {\sum }_{{l}^{′} = l - B / 2 + 1}^{l + B / 2} v [ {l}^{′} , k ] {i}^{*} [ {l}^{′} , k ] ,$$

with Eₕ=Σₛ₌₀^{S-1}h²[s] and B denoting the moving average length, or exponential average:

$${P}_{i i} [ l , k ] = λ {P}_{i i} [ l - 1 , k ] + ( 1 - λ ) - \frac{1}{{E}_{h}} {\vert i [ l , k ] \vert}^{2}$$

$${P}_{v i} [ l , k ] = λ {P}_{v i} [ l - 1 , k ] + ( 1 - λ ) \frac{1}{{E}_{h}} v [ l , k ] {i}^{*} [ l , k ]$$

where 0<λ<1 denotes the forgetting-factor.

The time support of the moving or exponential average may be selected based on the rate of variation of the battery impedance with changing SOC, temperature, age, and non-stationary dynamic load.

The PSDs may be updated at a frequency only when the load current is sufficiently above the measurement noise floor at that frequency, and may be frozen otherwise.

It is noted that the impedance estimate of equation (10) is in general not causal. A causal Wiener estimate may be obtained using spectral factorization of the current PSD, but to keep the computational cost low, the non-causal Wiener estimate may be used and the ECM may be relied upon to enforce causality.

The nonparametric impedance estimation method using multi-rate STFT processing along with Wiener filtering may have the advantage of very low computational cost and memory requirement. However, the requirement of a large analysis window length for impedance estimation at low frequencies may result in slower convergence speed.

The following describes the nonlinearity compensation method in accordance with embodiments of the present disclosure.

Compensation of the battery's nonlinearity by online nonlinearity compensation for power prediction 106 may be critical for accurate power prediction. The current and power limits for various time horizons are defined based on the terminal voltage at the end of a time horizon reaching a pre-defined system brownout voltage limit. The current and power limits may be predicted using ECM voltage simulations along with bisection search. Constant current and constant power limits may be predicted using the voltage simulations. The initial conditions for the voltage simulations may be based on the latest ECM states from the online ECM estimation. An offset may be added to account for unmodeled large time constants and OCV and coulomb-counter error and ensure voltage continuity.

Online nonlinearity compensation may be performed by modifying the online estimated ECM parameters during power prediction to account for the current dependence of the battery impedance. Specifically, the power limits may be predicted using the online estimated ECM with lookup table-based modifications to the ECM parameters to compensate for the impedance change due to the difference between the estimation current amplitude and prediction current amplitude. It is noted that the nonlinearity compensation may only be valid over the time and frequency support utilized for nonlinearity characterization.

For the RC ECM (e.g., ECM 200), the RC resistances may be modified for power prediction to correct for the impedance change expected based on the offline and online nonlinearity characterization:

$${z}_{RC} ( j ω , {i}_{pred} ) = {z}_{RC} ( j ω , {i}_{est} ) + ( {z}_{RC}^{char} ( j ω , {j}_{pred} ) - {z}_{RC}^{char} ( j ω , {i}_{est} ) ) , \qquad ( 11 )$$

where Z_{RC} denotes the RC ECM impedance with the notation:

$${z}_{RC} ( j ω , i ) = {r}_{0} + {\sum }_{n = 1}^{N} \frac{{r}_{n} ( i )}{1 + j ω {τ}_{n}}$$

used to make the current dependence of the RC ECM resistances and impedance explicit, iₑₛₜ is the load current amplitude during the online ECM estimation, i_{pred} is the load current amplitude for power limit prediction, and z_{RC}^{char} denotes the RC ECM impedance from the nonlinearity characterization for the operating SOC and temperature.

It is noted from equation (11) that the change in impedance with current amplitude expected based on the nonlinearity characterization may be used instead of the absolute impedance values.

Because the same fixed, logarithmically spaced RC time constants may be used in the nonlinearity characterization and online ECM estimation, the modified RC ECM resistances may be given simply by:

$${r}_{n} ( {i}_{pred} ) = {r}_{n} ( {i}_{est} ) + ( {r}_{n}^{char} ( {i}_{pred} ) - {r}_{n}^{char} ( {i}_{est} ) ) , n = 1 , … , N ,$$

where rₙ^{char} are the RC ECM resistances from the nonlinearity characterization lookup table for the operating SOC and temperature. This may significantly reduce the computational cost of the nonlinearity compensation process, enabling efficient power prediction. The RC ECM resistances may be interpolated as needed for values in between those available in the lookup table.

For the fractional-order ECM with current dependent charger-transfer resistance (e.g., EMC 300A), the impedance may be given by:

$${z}_{ZARC} ( j ω , i ) = {r}_{0} + \frac{{r}_{SEI}}{1 + {( j {ωτ}_{SEI} )}^{{ϕ}_{SEI}}} + \frac{{r}_{CT} ( i )}{1 + {( j {ωτ}_{CT} ( i ) )}^{{ϕ}_{CT}}} + \frac{{r}_{DIFF}}{1 + {( j {ωτ}_{DIFF} )}^{{ϕ}_{DIFF}}}$$

where the current dependence of the charge transfer resistance and time constant has been made explicit.

The modified charge transfer resistance may be calculated to correct for the change in charge transfer resistance expected based on the offline and online nonlinearity characterization:

$${r}_{CT} ( {i}_{pred} ) = {r}_{CT} ( {i}_{est} ) + ( {r}_{CT}^{char} ( {i}_{pred} ) - {r}_{CT}^{char} ( {i}_{est} ) ) ,$$

where r_{CT}^{char} denotes the charge transfer resistance from the nonlinearity characterization lookup table for the operating SOC and temperature. The charge transfer resistance may be interpolated as needed for values in between those available in the lookup table.

In this model, the CPE and exponent of the charge-transfer ZARC element are independent of current amplitude. The modified charge-transfer time constant is calculated using the modified charge-transfer resistance as:

$${τ}_{CT} ( {i}_{pred} ) = {( {r}_{CT} ( {i}_{pred} ) {y}_{CT} )}^{1 / {ϕ}_{CT}} .$$

It is noted that while the impedance nonlinearity over the entire modeled frequency range may be compensated in RC ECM 200, only the charge transfer impedance nonlinearity may be compensated in the fractional-order ECMs with the current dependent charger-transfer resistances (e.g., ECM 300A, 300B). In other fractional-order ECM embodiments with multiple current dependent parameters (e.g., ECM 300C), all of those parameters may similarly be modified to compensate for the battery nonlinearity over the entire modeled frequency range.

Information about the initial conditions during nonlinearity characterization (e.g., the dynamic load level when an online characterization is performed) may be used to further improve the nonlinearity compensation performance.

To reduce computational cost, the nonlinearity compensation may not be applied in some conditions. Compensation may not be needed when nonlinearity effects are small and may be ignored, for example, at high temperatures, for low current amplitudes and short time horizon power predictions.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A method for battery power management based on battery nonlinearity characterization and compensation using a physics-based nonlinear fractional-order equivalent circuit model (ECM), comprising:
measuring a battery current, a battery terminal voltage, and a battery temperature;
implementing the physics-based nonlinear fractional-order ECM comprising:
a linear model portion that represents current independent physics; and
a nonlinear model portion that represents current dependent physics;
wherein the current independent physics and the current dependent physics are separately maintained;
performing a nonlinearity characterization procedure using the physics-based nonlinear fractional-order ECM configured to:
characterize variations of a battery impedance of a battery with current amplitudes over a range of frequencies; and
create ECM parameter variations with current amplitudes by fitting impedance variations by nonlinear fractional-order ECMs;
performing an online estimation of a fractional-order ECM using a battery load current and a battery terminal voltage of the battery over time to generate an online estimated fractional-order ECM; and
modifying the online estimated fractional-order ECM using ECM parameter variations to compensate for nonlinearity of the battery.

2. The method of claim 1, wherein performing the nonlinearity characterization procedure comprises:
characterizing variations of battery impedance with current amplitudes over a range of frequencies for various respective current amplitudes, states-of-charge (SOCs), temperatures, and ages associated with the battery;
fitting the physics-based nonlinear fractional-order ECM to battery impedances; and
creating a lookup table comprising physics-based nonlinear fractional-order ECM parameter variations with respective current amplitudes for various SOCs, temperatures, and ages associated with the battery.

3. The method of claim 2, wherein performing the nonlinearity characterization procedure further comprises:
fitting the physics-based nonlinear fractional-order ECM with current dependent charge transfer resistances to battery impedances; and
creating a lookup table to store current dependent ECM charge transfer resistances for various respective current amplitudes, SOCs, temperatures, and ages.

4. The method of claim 2, wherein performing the nonlinearity characterization procedure further comprises:
fitting the physics-based nonlinear fractional-order ECM with multiple current dependent parameters to battery impedances; and
creating a lookup table to store multiple current dependent ECM parameters for various respective current amplitudes, SOCs, temperatures, and ages.

5. The method of claim 2, wherein performing the fitting comprises using a battery current and a battery terminal voltage over time to first estimate the battery impedance over a range of frequencies parametrically using a nonlinear resistor-capacitor (RC) ECM and then fitting the physics-based nonlinear fractional-order ECM to an estimated impedance using nonlinear least-squares optimization in a frequency domain.

6. The method of claim 1, further comprising predicting current limits and power limits by modifying the online estimated ECM using values of the ECM parameter variations stored in the lookup table to compensate for impedance changes due to differences between estimation current amplitudes and prediction current amplitudes.

7. The method of claim 1, further comprising modeling the linear model portion of the physics-based nonlinear fractional-order ECM using impedance elements that include at least one of capturing a response of a film-electrolyte interface and diffusion of reactants and/or products to the interface and a series resistance.

8. The method of claim 7, further comprising modeling the nonlinear model portion of the physics-based nonlinear fractional-order ECM using an impedance element that captures a response of a charge transfer process at a solid-film interface via a current dependent charge transfer resistance.

9. The method of claim 7, further comprising modeling the nonlinear model portion of the physics-based nonlinear fractional-order ECM using impedance elements that capture a response of a charge transfer process at a solid-film interface via two current dependent charge transfer resistances.

10. The method of claim 7, further comprising modeling the nonlinear model portion of the physics-based nonlinear fractional-order ECM using impedance elements that capture a response of a charge transfer process at a solid-film interface and diffusion of reactants and/or products to the solid-film interface, and wherein one or more of resistances and constant phase elements (CPEs) of the physics-based nonlinear fractional-order ECM are current dependent.

11. The method of claim 1, further comprising modeling the linear model portion of the physics-based nonlinear fractional-order ECM using an impedance element that captures a response of a film-electrolyte interface and a series resistance.

12. The method of claim 1, wherein the nonlinearity characterization procedure further comprises offline and online application of broadband pulse load currents to characterize the variations of the battery impedance with current amplitudes for various respective current amplitudes, states of charge (SOCs), temperatures, and ages.

13. The method of claim 12, further comprising performing the nonlinearity characterization procedure both during discharging and charging to characterize the variations of the battery impedance with current amplitudes for various respective current amplitudes, SOCs, temperatures, and ages.

14. The method of claim 12, wherein, in multi-cell systems, the nonlinearity characterization procedure further comprises moving charge between cells.

15. The method of claim 12, wherein the lookup table is further comprised of dynamic load levels of the battery when the nonlinearity characterization procedure is performed.

16. The method of claim 1, wherein performing the online estimation of the physics-based fractional-order ECM further comprises using a measured battery current and a battery terminal voltage over time to first estimate the battery impedance over a range of frequencies parametrically using a nonlinear RC ECM and then fitting the physics-based fractional-order ECM to an estimated impedance efficiently using nonlinear least-squares optimization in a frequency domain.

17. The method of claim 1, wherein performing the online estimation of the physics-based nonlinear fractional-order ECM further comprises using the measured battery load current and terminal voltage over time to estimate the battery impedance over a range of frequencies using nonparametric spectral analysis and Wiener filtering and fitting the physics-based nonlinear fractional-order ECM to an estimated impedance efficiently using nonlinear least-squares optimization in a frequency domain.

18. The method of claim 6, further comprising predicting the current limits and the power limits by modifying the online estimated nonlinear fractional-order ECM using ECM charge transfer resistances stored in the lookup table to compensate for impedance changes due to differences between estimation current amplitudes and prediction current amplitudes.

19. The method of claim 6, further comprising predicting the current limits and the power limits by modifying the online physics-based nonlinear fractional-order ECM using multiple current dependent ECM parameters stored in the lookup table to compensate for impedance changes due to differences between estimation current amplitudes and prediction current amplitudes.

20. The method of claim 1, further comprising outputting parameters and states of the physics-based nonlinear fractional-order ECM.

21. A method for battery power management based on battery nonlinearity characterization and compensation using a nonlinear resistor-capacitor (RC) equivalent circuit model (ECM), comprising:
measuring a battery current, a battery terminal voltage, and a battery temperature of a battery;
implementing the nonlinear RC ECM comprising:
fixed, logarithmically spaced time constants; and
current dependent resistances and capacitances;
constraining resistances of the nonlinear RC ECM to be nonnegative;
performing a nonlinearity characterization procedure using the nonlinear RC ECM configured to:
characterize variations of a battery impedance with current amplitudes over a range of frequencies; and
create ECM parameter variations with current amplitudes by fitting impedance variations by nonlinear RC ECMs;
performing online estimation of the nonlinear RC ECM using a battery current and a terminal voltage of the battery over time to generate an online estimated nonlinear RC ECM; and
modifying the online estimated nonlinear RC ECM using ECM parameter variations to compensate for nonlinearity of the battery.

22. The method of claim 21, wherein performing the nonlinearity characterization procedure further comprises:
characterizing variations of the battery impedance with current amplitudes over a range of frequencies for various respective current amplitudes, states of charge (SOCs), temperatures, and ages;
fitting nonlinear RC ECMs to the battery impedances; and
creating a lookup table comprising nonlinear RC ECM parameter variations with respective current amplitudes for various SOCs, temperatures, and ages associated with the battery.

23. The method of claim 22, wherein performing the nonlinearity characterization procedure further comprises:
fitting the nonlinear RC ECM with current dependent resistances and capacitances to the impedances; and
creating a lookup table to store current dependent ECM resistances and capacitances for various respective current amplitudes, SOCs, temperatures, and ages.

24. The method of claim 22, wherein performing the fitting further comprises using a measured battery load current and a terminal voltage over time to estimate resistances and capacitances of the nonlinear RC ECM with fixed, logarithmically spaced RC time constants and nonnegative resistances efficiently using constrained linear least-squares optimization and quadratic programming.

25. The method of claim 21, further comprising predicting current limits and power limits by online estimated nonlinear RC ECM using values of ECM parameter variations stored in the lookup table to compensate for impedance changes due to differences between estimation current amplitudes and prediction current amplitudes.

26. The method of claim 25, further comprising predicting the current limits and the power limits by modifying the online estimation of the RC ECM using ECM resistances and capacitances stored in the lookup table to compensate for impedance changes due to differences between estimation current amplitudes and prediction current amplitudes.

27. The method of claim 21, wherein the nonlinearity characterization procedure further comprises offline and online application of broadband pulse load currents to characterize variations of the battery impedance with current amplitudes for various respective current amplitudes, states of charge (SOCs), temperatures, and ages.

28. The method of claim 27, further comprising performing the nonlinearity characterization both during discharging and charging to characterize variations of the battery impedance with current amplitudes for various respective current amplitudes, SOCs, temperatures, and ages.

29. The method of claim 27, wherein, in multi-cell systems, the nonlinearity characterization procedure further comprises moving charge between cells.

30. The method of claim 27, wherein the lookup table is further comprised of dynamic load levels of the battery when nonlinearity characterization is performed.

31. The method of claim 21, wherein performing online estimation of the RC ECM further comprises using a measured battery load current and a terminal voltage over time to estimate the resistances and capacitances of the RC ECM with fixed, logarithmically spaced RC time constants and nonnegative resistances using projected gradient descent optimization.

32. The method of claim 21, further comprising outputting parameters and states of the nonlinear RC ECM.
